(19) United States
(12) Patent Application Publication
(10) Pub. No.: US 2014/0248422 A1
(43) Pub. Date: Sep. 4, 2014

(54) METHOD OF FABRICATING A CONDUCTIVE PATTERN WITH HIGH OPTICAL TRANSMISSION AND LOW VISIBILITY

(71) Applicants: Danliang Jin, The Woodlands, TX (US); Yieu Chyan, Conroe, TX (US); Ed S. Ramakrishnan, Spring, TX (US)

(72) Inventors: Danliang Jin, The Woodlands, TX (US); Yieu Chyan, Conroe, TX (US); Ed S. Ramakrishnan, Spring, TX (US)

(73) Assignee: UNI-PIXEL DISPLAYS, INC., The Woodlands, TX (US)

(21) Appl. No.: 14/259,278

(22) Filed: Apr. 23, 2014

Related U.S. Application Data
(63) Continuation-in-part of application No. 13/784,643, filed on Mar. 4, 2013.

(51) Int. Cl. H05K 3/18

(52) U.S. Cl. CPC H05K 3/182
USPC 427/97.3

(57) ABSTRACT

A method of fabricating a conductive pattern includes disposing an image of the conductive pattern on a substrate. The image includes material capable of being electroless plated. The image is electroless plated with a first metal forming a first plated image. The first plated image is electroless plated with a second metal forming a second plated image. The second metal passivates the first metal. The second plated image is bathed in an immersion bath comprising a darkening material.

### CROSS-REFERENCE TO RELATED APPLICATIONS

This application is a continuation-in-part of U.S. patent application Ser. No. 13/784,643, filed on Mar. 4, 2013, which is hereby incorporated by reference in its entirety.

### BACKGROUND OF THE INVENTION

A touch screen enabled system allows a user to control various aspects of the system by touch or gestures. For example, a user may interact directly with objects depicted on a display device by touch or gestures that are sensed by a touch sensor. The touch sensor typically includes a pattern of conductive lines disposed on a substrate configured to sense touch.

Touch screens are commonly found in consumer systems, commercial systems, and industrial systems including, but not limited to, smartphones, tablet computers, laptop computers, desktop computers, printers, monitors, televisions, appliances, kiosks, copiers, desktop phones, automotive display systems, portable gaming devices, and gaming consoles.

### BRIEF SUMMARY OF THE INVENTION

According to one aspect of one or more embodiments of the present invention, a method of fabricating a conductive pattern includes disposing an image of the conductive pattern on a substrate. The image includes material capable of being electroless plated. The image is electroless plated with a first metal forming a first plated image. The first plated image is electroless plated with a second metal forming a second plated image. The second metal passivates the first metal. The second plated image is bathed in an immersion bath comprising a darkening material.

According to one aspect of one or more embodiments of the present invention, a method of fabricating a conductive pattern includes disposing an image of the conductive pattern on a substrate. The image includes material capable of being electroless plated. The image is electroless plated with a first metal forming a first plated image. The first plated image is electroless plated with a second metal forming a second plated image. The second metal passivates the first metal. The second plated image is electroless plated with a darkening material.

Other aspects of the present invention will be apparent from the following description and claims.

### BRIEF DESCRIPTION OF THE DRAWINGS

FIG. 1 shows a cross section of a touch screen in accordance with one or more embodiments of the present invention.

FIG. 2 shows a schematic view of a touch screen enabled computing system in accordance with one or more embodiments of the present invention.

FIG. 3 shows a functional representation of a touch sensor as part of a touch screen in accordance with one or more embodiments of the present invention.

FIG. 4A shows a cross-section of a touch sensor with conductive patterns disposed on opposing sides of a transparent substrate in accordance with one or more embodiments of the present invention.

FIG. 4B shows a cross-section of a touch sensor with a first conductive pattern disposed on a first transparent substrate and a second conductive pattern disposed on a second transparent substrate in accordance with one or more embodiments of the present invention.

FIG. 4C shows a cross-section of a touch sensor with a first conductive pattern disposed on a first transparent substrate and a second conductive pattern disposed on a second transparent substrate in accordance with one or more embodiments of the present invention.

FIG. 4D shows a cross-section of a touch sensor with a first conductive pattern disposed on a first transparent substrate and a second conductive pattern disposed on a second transparent substrate in accordance with one or more embodiments of the present invention.

FIG. 5 shows a first conductive pattern disposed on a transparent substrate in accordance with one or more embodiments of the present invention.

FIG. 6 shows a second conductive pattern disposed on a transparent substrate in accordance with one or more embodiments of the present invention.

FIG. 7 shows a portion of a touch sensor in accordance with one or more embodiments of the present invention.

FIG. 8 shows a flexographic printing station in accordance with one or more embodiments of the present invention.

FIG. 9 shows a method of fabricating a conductive pattern in accordance with one or more embodiments of the present invention.

FIG. 10 shows a method of fabricating a conductive pattern in accordance with one or more embodiments of the present invention.

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are set forth in order to provide a thorough understanding of the present invention. In other instances, well-known features to one of ordinary skill in the art are not described to avoid obscuring the description of the present invention.

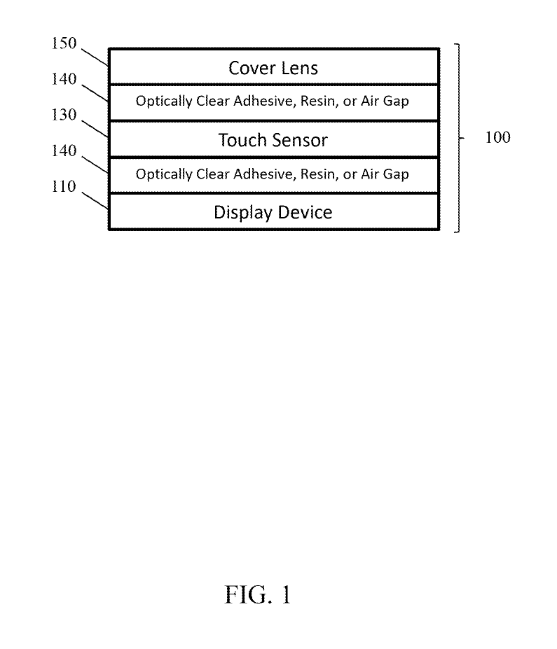

FIG. 1 shows a cross-section of a touch screen 100 in accordance with one or more embodiments of the present invention. Touch screen 100 includes a display device 110. Display device 110 may be a Liquid Crystal Display (“LCD”), Light-Emitting Diode (“LED”), Organic Light-Emitting Diode (“OLED”), Active Matrix Organic Light-Emitting Diode (“AMOLED”), In-Plane Switching (“IPS”), or other type of display device suitable for use as part of a touch screen application or design. In one or more embodiments of the present invention, touch screen 100 may include a touch sensor 130 that overlays at least a portion of a viewable area of display device 110. In certain embodiments, an optically clear adhesive or resin 140 may bond a bottom side of touch sensor 130 to a top, or user-facing, side of display device 110. In other embodiments, an isolation layer, or air gap, 140 may separate the bottom side of touch sensor 130 from the top, or user-facing, side of display device 110. A cover lens 150 may overlay touch sensor 130. Cover lens 150 may be composed of glass, plastic, film, or other material. In certain embodiments, an optically clear adhesive or resin 140 may bond a bottom side of cover lens 150 to a top, or user-facing, side of touch sensor 130. In other embodiments, an isolation layer, or air gap, 140 may separate the bottom side of cover lens 150 and the top, or user-facing, side of touch sensor 130. A top side of cover lens 150 faces the user and protects the underlying components of touch screen 100. In one or more embodiments of the present invention, touch sensor 130, or the function that it implements, may be integrated into the display device 110 stack (not independently illustrated). One of ordinary skill in the art will recognize that touch sensor 130 may be a capacitive, resistive, optical, acoustic, or any other type of touch sensor capable of sensing touch.

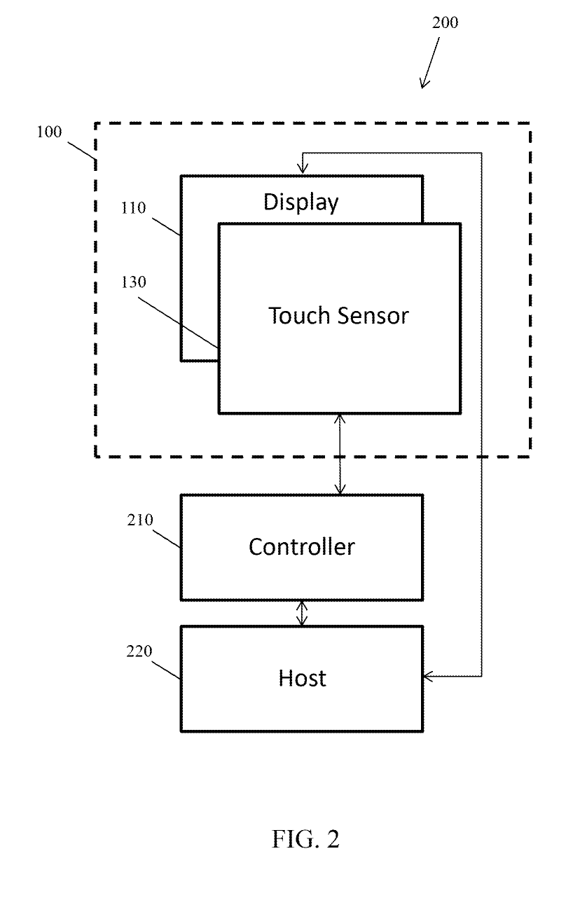

FIG. 2 shows a schematic view of a touch screen enabled computing system 200 in accordance with one or more embodiments of the present invention. Computing system 200 may be a consumer computing system, commercial computing system, or industrial computing system including, but not limited to, smartphones, tablet computers, laptop computers, desktop computers, printers, monitors, televisions, appliances, kiosks, automatic teller machines, copiers, desktop phones, automotive display systems, portable gaming devices, gaming consoles, or other applications or designs suitable for use with touch screen 100.

Computing system 200 may include one or more printed or flex circuits (not shown) on which one or more processors (not shown) and system memory (not shown) may be disposed. Each of the one or more processors may be a single-core processor (not shown) or a multi-core processor (not shown) capable of executing software instructions. Multi-core processors typically include a plurality of processor cores disposed on the same physical die (not shown) or a plurality of processor cores disposed on multiple die (not shown) disposed within the same mechanical package (not shown). Computing system 200 may include one or more input/output devices (not shown), one or more local storage devices (not shown) including solid-state memory, a fixed disk drive, a fixed disk drive array, or any other non-transitory computer readable medium, a network interface device (not shown), and/or one or more network storage devices (not shown) including network-attached storage devices and cloud-based storage devices.

In certain embodiments, touch screen 100 may include touch sensor 130 that overlays at least a portion of a viewable area of display device 110. In other embodiments, touch sensor 130, or the function that it implements, may be integrated into display device 110 (not independently illustrated). Controller 210 electrically drives at least a portion of touch sensor 130. Touch sensor 130 senses touch (capacitance, resistance, optical, or acoustic) and conveys information corresponding to the sensed touch to controller 210. In typical applications, the manner in which the sensing of touch is measured, tuned, and/or filtered may be configured by controller 210. In addition, controller 210 may recognize one or more gestures based on the sensed touch or touches. Controller 210 provides host 220 with touch or gesture information corresponding to the sensed touch or touches. Host 220 may use this touch or gesture information as user input and respond in an appropriate manner. In this way, the user may interact with computing system 200 by touch or gestures on touch screen 100. In certain embodiments, host 220 may be the one or more printed or flex circuits (not shown) on which the one or more processors (not shown) are disposed. In other embodiments, host 220 may be a subsystem or any other part of computing system 200 that is configured to interface with display device 110 and controller 210.

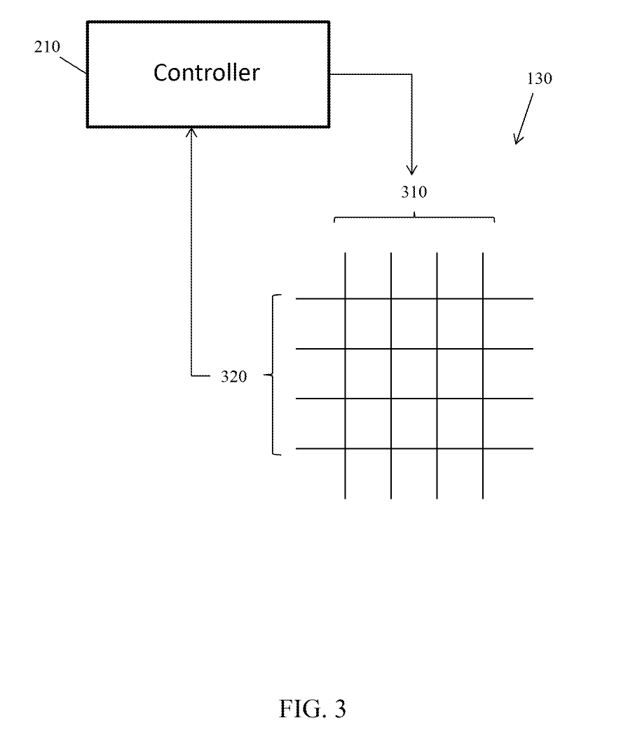

FIG. 3 shows a functional representation of a touch sensor 130 as part of a touch screen 100 in accordance with one or more embodiments of the present invention. In certain embodiments, touch sensor 130 may be viewed as a plurality of column lines 310 and a plurality of row lines 320 arranged as a mesh grid. The number of column lines 310 and the number of row lines 320 may not be the same and may vary based on an application or a design. The apparent intersections of column lines 310 and row lines 320 may be viewed as uniquely addressable locations of touch sensor 130. In operation, controller 210 may electrically drive one or more row lines 320 and touch sensor 130 may sense touch on one or more column lines 310 that are sampled by controller 210. One of ordinary skill in the art will recognize that the role of row lines 320 and column lines 310 may be reversed such that controller 210 electrically drives one or more column lines 310 and touch sensor 130 senses touch on one or more row lines 320 that are sampled by controller 210.

In certain embodiments, controller 210 may interface with touch sensor 130 by a scanning process. In such an embodiment, controller 210 may electrically drive a selected row line 320 (or column line 310) and sample all column lines 310 (or row lines 320) that intersect the selected row line 320 (or the selected column line 310) by measuring, for example, capacitance at each intersection. This process may be continued through all row lines 320 (or all column lines 310) such that capacitance is measured at each uniquely addressable location of touch sensor 130 at predetermined intervals. Controller 210 may allow for the adjustment of the scan rate depending on the needs of a particular application or design. One of ordinary skill in the art will recognize that the scanning process discussed above may also be used with other touch sensor technologies in accordance with one or more embodiments of the present invention.

In other embodiments, controller 210 may interface with touch sensor 130 by an interrupt driven process. In such an embodiment, a touch or a gesture generates an interrupt to controller 210 that triggers controller 210 to read one or more of its own registers that store sensed touch information sampled from touch sensor 130 at predetermined intervals. One of ordinary skill in the art will recognize that the mechanism by which touch or gestures are sensed by touch sensor 130 and sampled by controller 210 may vary based on an application or a design in accordance with one or more embodiments of the present invention.

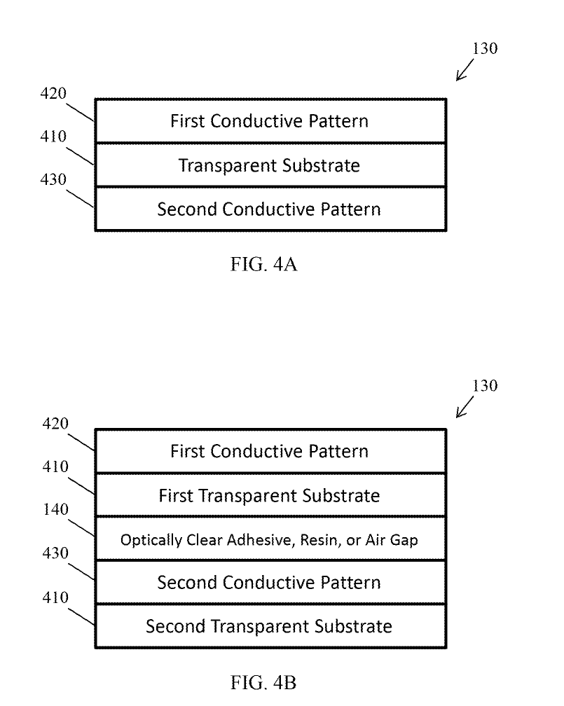

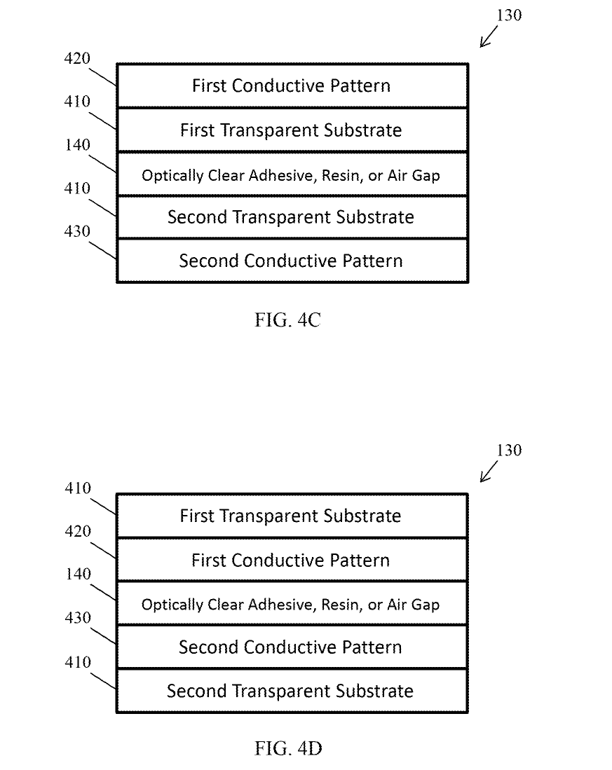

FIG. 4A shows a cross-section of a touch sensor 130 with conductive patterns 420 and 430 disposed on opposing sides of a transparent substrate 410 in accordance with one or more embodiments of the present invention. In certain embodiments, touch sensor 130 may include a first conductive pattern 420 disposed on a top, or user-facing, side of a transparent substrate 410 and a second conductive pattern 430 disposed on a bottom side of the transparent substrate 410. One of ordinary skill in the art will recognize that a conductive pattern may be any shape or pattern of one or more conductors in accordance with one or more embodiments of the present invention.

FIG. 4B shows a cross-section of a touch sensor 130 with a first conductive pattern 420 disposed on a first transparent substrate 410 and a second conductive pattern 430 disposed on a second transparent substrate 410 in accordance with one or more embodiments of the present invention. In certain embodiments, touch sensor 130 may include first conductive pattern 420 disposed on a top, or user-facing, side of the first transparent substrate 410 and second conductive pattern 430 disposed on a top side of the second transparent substrate 410. The first conductive pattern 420 may overlay the second conductive pattern 430 at a predetermined alignment that may include an offset. In certain embodiments, the first transparent substrate 410 may be bonded to the second transparent substrate 410 by a lamination process (not shown). In other embodiments, the first transparent substrate 410 may be bonded to the second transparent substrate 410 by an optically clear adhesive or resin 140. In still other embodiments, the first transparent substrate 410 and the second transparent substrate 410 may be secured in place and there may be an isolation layer, or air gap, 140 disposed between the bottom side of the first transparent substrate 410 and the second conductive pattern 430 disposed on the top side of the second transparent substrate 410.

FIG. 4C shows a cross-section of a touch sensor 130 with a first conductive pattern 420 disposed on a first transparent substrate 410 and a second conductive pattern 430 disposed on a second transparent substrate 410 in accordance with one or more embodiments of the present invention. In certain embodiments, touch sensor 130 may include first conductive pattern 420 disposed on a top, or user-facing, side of first transparent substrate 410 and second conductive pattern 430 disposed on a bottom side of second transparent substrate 410. The first conductive pattern 420 may overlay the second conductive pattern 430 at a predetermined alignment that may include an offset. In certain embodiments, the first transparent substrate 410 may be bonded to the second transparent substrate 410 by a lamination process (not shown). In other embodiments, the first transparent substrate 410 may be bonded to the second transparent substrate 410 by an optically clear adhesive or resin 140. In still other embodiments, the first transparent substrate 410 and the second transparent substrate 410 may be secured in place and there may be an isolation layer, or air gap, 140 disposed between the bottom side of the first transparent substrate 410 and the top side of the second transparent substrate 410.

FIG. 4D shows a cross-section of a touch sensor 130 with a first conductive pattern 420 disposed on a first transparent substrate 410 and a second conductive pattern 430 disposed on a second transparent substrate 410 in accordance with one or more embodiments of the present invention. In certain embodiments, touch sensor 130 may include first conductive pattern 420 disposed on a bottom side of the first transparent substrate 410 and second conductive pattern 430 disposed on a top side of the second transparent substrate 410. The first conductive pattern 420 may overlay the second conductive pattern 430 at a predetermined alignment that may include an offset. In certain embodiments, the first transparent substrate 410 may be bonded to the second transparent substrate 410 by a lamination process (not shown). In other embodiments, the first transparent substrate 410 may be bonded to the second transparent substrate 410 by an optically clear adhesive or resin 140. In still other embodiments, the first transparent substrate 410 and the second transparent substrate 410 may be secured in place and there may be an isolation layer, or air gap, 140 disposed between the first conductive pattern 420 disposed on the bottom side of the first transparent substrate 410 and the second conductive pattern 430 disposed on the top side of the second transparent substrate 410.

One of ordinary skill in the art will recognize that a conductive pattern (e.g., first conductive pattern 420 or second conductive pattern 430) may be comprised of metal, metal alloys, metal oxides, metal nanowires, metal nanoparticle inks, metal nanoparticle coatings, metallic lines, metallic wires, transparent conductors including Indium Tin Oxide (“ITO”), Poly(3,4-ethylenedioxythiophene) (“PEDOT”), carbon nanotubes, graphene, and/or any other conductive material capable of being disposed on a transparent substrate in accordance with one or more embodiments of the present invention. One of ordinary skill in the art will also recognize that other touch sensor 130 stackups, including those that vary in the number, type, or organization of transparent substrate(s) and/or conductive pattern(s) are within the scope of one or more embodiments of the present invention. For example, one of ordinary skill in the art will recognize that one or more of the embodiments depicted in FIGS. 4A through 4D, as well as other embodiments not shown, may be used in applications where touch sensor 130 is integrated into display device 110 in accordance with one or more embodiments of the present invention.

A conductive pattern (e.g., first conductive pattern 420 or second conductive pattern 430) may be disposed on one or more transparent substrates 410 by any process suitable for disposing conductive lines or features on substrate. Suitable processes may include, for example, printing processes, vacuum-based deposition processes, solution coating processes, or cure/etch processes that either form conductive lines or features on substrate or form seed lines or features on substrate that may be further processed to form conductive lines or features on substrate. Printing processes may include flexographic printing, including the flexographic printing of a catalytic ink image that may be metallized by an electroless plating process or immersion bath process or direct flexographic printing of conductive ink or other materials, gravure printing, inkjet printing, rotary printing, or stamp printing. Deposition processes may include pattern-based deposition, chemical vapor deposition, electro deposition, physical vapor deposition, or casting. Cure/etch processes may include optical or UV-based photolithography, e-beam/ion-beam lithography, x-ray lithography, interference lithography, scanning probe lithography, imprint lithography, or magneto lithography. One of ordinary skill in the art will recognize that any process or combination of processes, suitable for disposing conductive lines or features on substrate, may be used in accordance with one or more embodiments of the present invention.

With respect to transparent substrate 410, transparent means capable of transmitting a substantial portion of visible light through the substrate. In certain embodiments, transparent substrate 410 may be polyethylene terephthalate (“PET”), polyethylene naphthalate (“PEN”), cellulose acetate (“TAC”), cycloaliphatic hydrocarbons (“COP”), polymethylmethacrylates (“PMMA”), polyimide (“PI”), bi-axially-oriented polypropylene (“BOPP”), polyester, polycarbonate, glass, copolymers, blends, or combinations thereof. In other embodiments, transparent substrate 410 may be any other transparent material suitable for use as a touch sensor substrate. One of ordinary skill in the art will recognize that the composition of transparent substrate 410 may vary based on an application or design in accordance with one or more embodiments of the present invention.

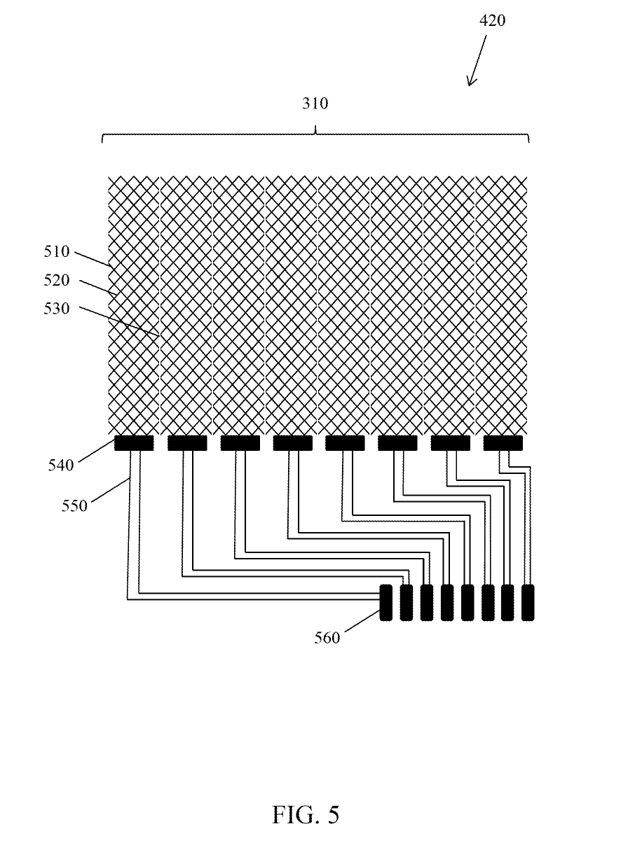

FIG. 5 shows a first conductive pattern 420 disposed on a transparent substrate (e.g., transparent substrate 410) in accordance with one or more embodiments of the present invention. In certain embodiments, first conductive pattern 420 may include a mesh formed by a plurality of parallel conductive lines oriented in a first direction 510 and a plurality of parallel conductive lines oriented in a second direction 520 that are disposed on a side of a transparent substrate (e.g., transparent substrate 410). One of ordinary skill in the art will recognize that the number of parallel conductive lines oriented in the first direction 510 and/or the number of parallel conductive lines oriented in the second direction 520 may vary based on an application or design. One of ordinary skill in the art will also recognize that a size of first conductive pattern 420 may vary based on an application or a design. In other embodiments, first conductive pattern 420 may include any other shape or pattern formed by one or more conductive lines or features (not independently illustrated). One of ordinary skill in the art will recognize that a conductive pattern is not limited to parallel conductive lines and could be any one or more of predetermined orientations of line segments, random orientations of line segments, curved line segments, conductive particles, polygons, or any other shape(s) or pattern(s) comprised of electrically conductive material (not independently illustrated) in accordance with one or more embodiments of the present invention.

In certain embodiments, the plurality of parallel conductive lines oriented in the first direction 510 may be perpendicular to the plurality of parallel conductive lines oriented in the second direction 520, thereby forming the mesh. In other embodiments, the plurality of parallel conductive lines oriented in the first direction 510 may be angled relative to the plurality of parallel conductive lines oriented in the second direction 520, thereby forming the mesh. One of ordinary skill in the art will recognize that the relative angle between the plurality of parallel conductive lines oriented in the first direction 510 and the plurality of parallel conductive lines oriented in the second direction 520 may vary based on an application or a design in accordance with one or more embodiments of the present invention.

In certain embodiments, a plurality of breaks 530 may partition first conductive pattern 420 into a plurality of column lines 310, each electrically partitioned from the others. One of ordinary skill in the art will recognize that the number of breaks 530 and the number of column lines 310 may vary based on an application or design in accordance with one or more embodiments of the present invention. Each column line 310 may route to a channel pad 540. Each channel pad 540 may route to an interface connector 560 by way of one or more interconnect conductive lines 550. Interface connectors 560 may provide a connection interface between a touch sensor (130 of FIG. 1) and a controller (210 of FIG. 2).

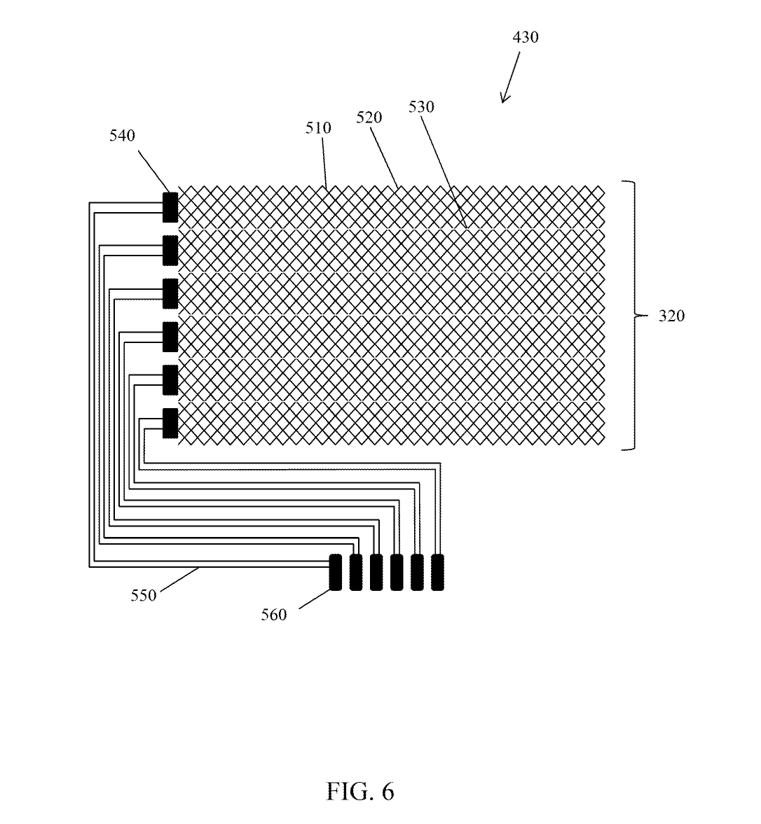

FIG. 6 shows a second conductive pattern 430 disposed on a second transparent substrate (e.g., transparent substrate 410) in accordance with one or more embodiments of the present invention. In certain embodiments, second conductive pattern 430 may include a mesh formed by a plurality of parallel conductive lines oriented in a first direction 510 and a plurality of parallel conductive lines oriented in a second direction 520 that are disposed on a side of a transparent substrate (e.g., transparent substrate 410). One of ordinary skill in the art will recognize that the number of parallel conductive lines oriented in the first direction 510 and/or the number of parallel conductive lines oriented in the second direction 520 may vary based on an application or design. In certain embodiments, the second conductive pattern 430 may be substantially similar in size to the first conductive pattern 420. One of ordinary skill in the art will recognize that a size of the second conductive pattern 430 may vary based on an application or a design. In other embodiments, second conductive pattern 430 may include any other shape or pattern formed by one or more conductive lines or features (not independently illustrated). One of ordinary skill in the art will recognize that a conductive pattern is not limited to parallel conductive lines and could be any one or more of predetermined orientations of line segments, random orientations of line segments, curved line segments, conductive particles, polygons, or any other shape(s) or pattern(s) comprised of electrically conductive material (not independently illustrated) in accordance with one or more embodiments of the present invention.

In certain embodiments, the plurality of parallel conductive lines oriented in the first direction 510 may be perpendicular to the plurality of parallel conductive lines oriented in the second direction 520, thereby forming the mesh. In other embodiments, the plurality of parallel conductive lines oriented in the first direction 510 may be angled relative to the plurality of parallel conductive lines oriented in the second direction 520, thereby forming the mesh. One of ordinary skill in the art will recognize that the relative angle between the plurality of parallel conductive lines oriented in the first direction 510 and the plurality of parallel conductive lines oriented in the second direction 520 may vary based on an application or a design in accordance with one or more embodiments of the present invention.

In certain embodiments, a plurality of breaks 530 may partition second conductive pattern 430 into a plurality of row lines 320, each electrically partitioned from the others. One of ordinary skill in the art will recognize that the number of breaks 530 and the number of row lines 320 may vary based on an application or design in accordance with one or more embodiments of the present invention. Each row line 320 may route to a channel pad 540. Each channel pad 540 may route to an interface connector 560 by way of one or more interconnect conductive lines 550. Interface connectors 560 may provide a connection interface between the touch sensor (130 of FIG. 1) and the controller (210 of FIG. 2).

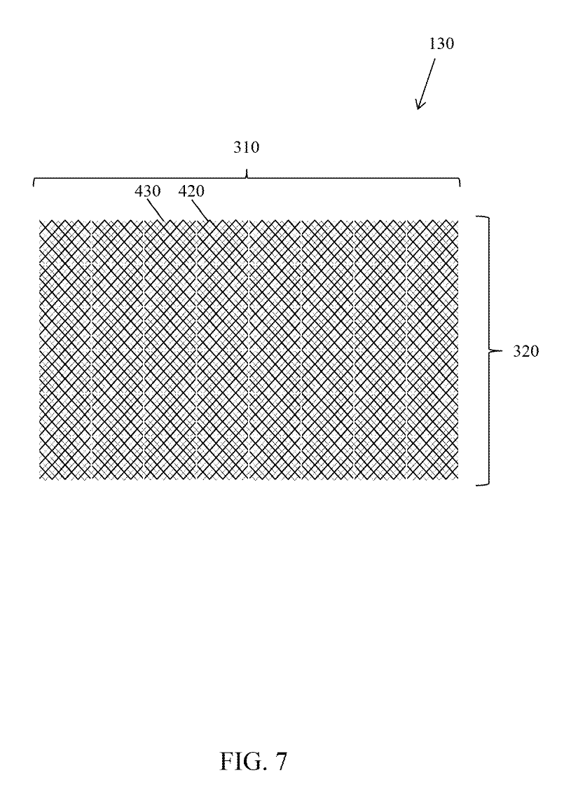

FIG. 7 shows a portion of a touch sensor 130 in accordance with one or more embodiments of the present invention. In certain embodiments, a touch sensor 130 may be formed, for example, by disposing a first conductive pattern 420 on a top, or user-facing, side of a transparent substrate (e.g., transparent substrate 410) and disposing a second conductive pattern 430 on a bottom side of the transparent substrate (e.g., transparent substrate 410). In other embodiments, a touch sensor 130 may be formed, for example, by disposing a first conductive pattern 420 on a side of a first transparent substrate (e.g., transparent substrate 410) and disposing a second conductive pattern 430 on a side of a second transparent substrate (e.g., transparent substrate 410). One of ordinary skill in the art will recognize that the disposition of the conductive pattern or patterns may vary based on the touch sensor 130 stackup in accordance with one or more embodiments of the present invention. In embodiments that use two conductive patterns, the first conductive pattern 420 and the second conductive pattern 430 may be horizontally and/or vertically offset relative to one another. The offset between the first conductive pattern 420 and the second conductive pattern 430 may vary based on an application or a design.

In certain embodiments, the first conductive pattern 420 may include a plurality of parallel conductive lines oriented in a first direction (510 of FIG. 5) and a plurality of parallel conductive lines oriented in a second direction (520 of FIG. 5) that form a mesh that is partitioned by a plurality of breaks (530 of FIG. 5) into electrically partitioned column lines 310. In certain embodiments, the second conductive pattern 430 may include a plurality of parallel conductive lines oriented in a first direction (510 of FIG. 6) and a plurality of parallel conductive lines oriented in a second direction (520 of FIG. 6) that form a mesh that is partitioned by a plurality of breaks (530 of FIG. 6) into electrically partitioned row lines 320. In operation, a controller (210 of FIG. 2) may electrically drive one or more row lines 320 (or column lines 310) and touch sensor 130 senses touch on one or more column lines 310 (or row lines 320) sampled by the controller (210 of FIG. 2). In other embodiments, the disposition and/or the role of the first conductive pattern 420 and the second conductive pattern 430 may be reversed.

In certain embodiments, one or more of the plurality of parallel conductive lines oriented in a first direction (510 of FIG. 5 or FIG. 6), one or more of the plurality of parallel conductive lines oriented in a second direction (520 of FIG. 5 or FIG. 6), one or more of the plurality of breaks (530 of FIG. 5 or FIG. 6), one or more of the plurality of channel pads (540 of FIG. 5 or FIG. 6), one or more of the plurality of interconnect conductive lines (550 of FIG. 5 or FIG. 6), and/or one or more of the plurality of interface connectors (560 of FIG. 5 or FIG. 6) of the first conductive pattern 420 or second conductive pattern 430 may have different line widths and/or different orientations. In addition, the number of parallel conductive lines oriented in the first direction (510 of FIG. 5 or FIG. 6), the number of parallel conductive lines oriented in the second direction (520 of FIG. 5 or FIG. 6), and the line-to-line spacing between them may vary based on an application or a design. One of ordinary skill in the art will recognize that the size, configuration, and design of each conductive pattern may vary based on an application or a design in accordance with one or more embodiments of the present invention.

In certain embodiments, one or more of the plurality of parallel conductive lines oriented in the first direction (510 of FIG. 5 or FIG. 6) and one or more of the plurality of parallel conductive lines oriented in the second direction (520 of FIG. 5 or FIG. 6) may have a line width less than approximately 5 micrometers. In other embodiments, one or more of the plurality of parallel conductive lines oriented in the first direction (510 of FIG. 5 or FIG. 6) and one or more of the plurality of parallel conductive lines oriented in the second direction (520 of FIG. 5 or FIG. 6) may have a line width in a range between approximately 5 micrometers and approximately 10 micrometers. In still other embodiments, one or more of the plurality of parallel conductive lines oriented in the first direction (510 of FIG. 5 or FIG. 6) and one or more of the plurality of parallel conductive lines oriented in the second direction (520 of FIG. 5 or FIG. 6) may have a line width in a range between approximately 10 micrometers and approximately 50 micrometers. In still other embodiments, one or more of the plurality of parallel conductive lines oriented in the first direction (510 of FIG. 5 or FIG. 6) and one or more of the plurality of parallel conductive lines oriented in the second direction (520 of FIG. 5 or FIG. 6) may have a line width greater than approximately 50 micrometers. One of ordinary skill in the art will recognize that the shape and width of one or more of the plurality of parallel conductive lines oriented in the first direction (510 of FIG. 5 or FIG. 6) and one or more of the plurality of parallel conductive lines oriented in the second direction (520 of FIG. 5 or FIG. 6) may vary based on an application or a design in accordance with one or more embodiments of the present invention.

In certain embodiments, one or more of the plurality of channel pads (540 of FIG. 5 or FIG. 6), one or more of the plurality of interconnect conductive lines (550 of FIG. 5 or FIG. 6), and/or one or more of the plurality of interface connectors (560 of FIG. 5 or FIG. 6) may have a different width or orientation. In addition, the number of channel pads (540 of FIG. 5 or FIG. 6), interconnect conductive lines (550 of FIG. 5 or FIG. 6), and/or interface connectors (560 of FIG. 5 or FIG. 6) and the line-to-line spacing between them may vary based on an application or a design. One of ordinary skill in the art will recognize that the size, configuration, and design of each channel pad (540 of FIG. 5 or FIG. 6), interconnect conductive line (550 of FIG. 5 or FIG. 6), and/or interface connector (560 of FIG. 5 or FIG. 6) may vary based on an application or a design in accordance with one or more embodiments of the present invention.

In typical applications, each of the one or more channel pads (540 of FIG. 5 and FIG. 6), interconnect conductive lines (550 of FIG. 5 and FIG. 6), and/or interface connectors (560 of FIG. 5 and FIG. 6) have a width substantially larger than each of the plurality of parallel conductive lines oriented in a first direction (510 of FIG. 5 or FIG. 6) or each of the plurality of parallel conductive lines oriented in a second direction (520 of FIG. 5 or FIG. 6). One of ordinary skill in the art will recognize that the size, configuration, and design as well as the number, shape, and width of channel pads (540 of FIG. 5 or FIG. 6), interconnect conductive lines (550 of FIG. 5 or FIG. 6), and/or interface connectors (560 of FIG. 5 or FIG. 6) may vary based on an application or a design in accordance with one or more embodiments of the present invention.

A conductive pattern used in a touch sensor application may be evaluated based on a number of performance metrics including, but not limited to, one or more of feature sizes, electrical conductivity, electrical resistivity, optical transmission, visibility, reliability, and/or resistance to environmental degradation. One of ordinary skill in the art will recognize that a conductive pattern used in a non-touch sensor application may be evaluated based on one or more of the above-noted performance metrics as well as others in accordance with one or more embodiments of the present invention.

Typically, one or more performance metrics are related such that a change in one may result in a change in another. In some instances, an improvement in one performance metric may result in an improvement in another. However, in some instances, an improvement in one performance metric may diminish another performance metric. Consequently, the interplay between various performance metrics is complicated. For example, with respect to electrical performance metrics, it is generally desirable to increase the electrical conductivity and reduce the electrical resistivity of a conductive pattern. The conductive pattern must provide sufficient electrical conductivity to function and low electrical resistivity is desirable because, as the electrical resistivity increases, the speed, or scan rate, at which a touch sensor may operate decreases. However, as a feature size of a conductive pattern, such as, for example, a line width and/or a line height of a conductive line or feature decreases, the electrical conductivity decreases and the electrical resistivity increases. This is particularly problematic as a line width of a conductive line or feature of a conductive pattern is in the micrometer range.

With respect to optical performance metrics, it is generally desirable to increase the optical transmission of the conductive pattern in a touch sensor application. Optical transmission relates to the ability of the conductive pattern to transmit the underlying image of the display device at an acceptable quality level. In addition, it is generally desirable to reduce the visibility of the conductive pattern in a touch sensor application. Visibility relates to the visibility of the conductive pattern itself to an end user under normal operating conditions, which may include evaluation when the underlying display device is on and also when the underlying display device is off. The optical transmission of the conductive pattern may be improved by reducing the feature size of the conductive pattern. However, the optical transmission may be impacted by the design and/or the composition of the conductive pattern and the constituent conductive lines or features. While the visibility of the conductive pattern may or may not be reduced by a reduction in feature size, the conductive pattern may be rendered more visible to an end user as a result of the color, the reflectivity, and/or optical scattering phenomena of the conductive pattern or passivation layer applied to the conductive pattern.

With respect to reliability and environmental performance metrics, a conductive pattern is prone to degradation from use and other causes over time. Depending on the type of degradation, the reliability may be affected by the development of electrical opens or electrical shorts upon continued operation. As a consequence, the reliability, functionality, and useable life of the conductive pattern, or a touch sensor in which it may be disposed, may be substantially reduced. Degradation may occur as a result of oxidation, day-to-day usage, electro-migration, airborne, solution-based, or liquid-based exposure to the environment, and/or exposure to corrosive agents such as soft drinks, coffee, oils, bodily fluids, acids, caustics, atmospheric pollutants, environmental pollutants, salt water, or water with contaminants such as salts, minerals, or ions. In addition to the reduction in reliability and functionality, degradation such as, for example, corrosion may render one or more of the conductive patterns more visually apparent to an end user prior to failure. Corrosion typically renders affected portions of a conductive pattern black, blue, or green, or other color depending on the corroded metal. In this way, degradation may reduce the quality of use prior to failure.

Copper and copper alloys provide high conductivity, high flexibility, high electroless and electrolytic plate-ability, and low material cost. As such, the use of copper or copper alloys as a base metal in a conductive pattern may be desirable. However, the use of copper or copper alloys in a conductive pattern presents a number of challenges. For example, copper or copper alloys exhibit a copper color that may be reflective or prone to optical scattering phenomena, rendering a conductive pattern more visible to an end user under normal operating conditions. In addition, copper or copper alloys are prone to surface oxidation on exposure to ambient conditions and are prone to corrosion in certain environmental conditions. In an attempt to address these issues, an oxide or sulfide layer may be deposited on the copper or copper alloy or a layer of other material may be reactively formed on the copper or copper alloy. However, these layers consume a substantial portion of the copper or copper alloy in the process, potentially decreasing conductivity and increasing resistivity, and potentially become insulators. As a consequence, the copper or copper alloy has to be thick, such as, for example, greater than 5 micrometers, to start with because a substantial amount of the copper or copper alloy is consumed. However, copper or copper alloy having such a thickness may result in stress, poor adhesion, and other failure modes, especially when deposited by an electroless plating process. In addition, the copper or copper alloys may be prone to electro-migration. As such, it is difficult to achieve micrometer-fine feature sizes in conductive patterns comprised of copper or copper alloys.

Consequently, a conductive pattern typically represents a compromise of feature sizes, electrical conductivity, electrical resistivity, optical transmission, visibility, reliability, and/or resistance to environmental degradation as well as manufacturing expense, manufacturing time, and manufacturing complexity. As such, as one or more feature sizes shrink, it is expensive, time consuming, and difficult to produce a conductive pattern suitable for use in, for example, a touch sensor application or design.

In one or more embodiments of the present invention, a method of fabricating a conductive pattern provides a conductive pattern with high optical transmission and low visibility suitable for use in, for example, a touch sensor application or design. In addition, in one or more embodiments of the present invention, a method of fabricating a conductive pattern provides a conductive pattern that improves reliability and resists environmental degradation. In addition, in one or more embodiments of the present invention, a method of fabricating a conductive pattern reduces manufacturing expense, manufacturing time, and manufacturing complexity.

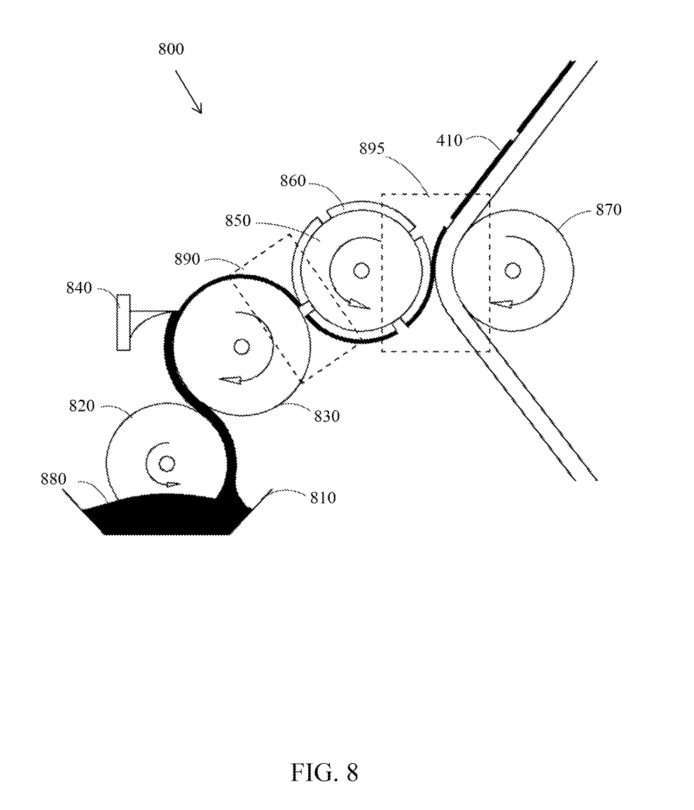

FIG. 8 shows a flexographic printing station 800 in accordance with one or more embodiments of the present invention. Flexographic printing station 800 may include an ink pan 810, an ink roll 820 (also referred to as a fountain roll), an anilox roll 830 (also referred to as a meter roll), a doctor blade 840, a printing plate cylinder 850, a flexographic printing plate 860, and an impression cylinder 870.

In operation, ink roll 820 transfers ink 880 from ink pan 810 to anilox roll 930. In certain embodiments, ink 880 may be a precursor ink, a catalytic ink, or a catalytic alloy ink that serves as a plating seed suitable for metallization by electroless plating or other buildup process. For example, ink 880 may be a catalytic ink that comprises one or more of silver, nickel, copper, palladium, cobalt, platinum group metals, alloys thereof, or other catalytic particles. In other embodiments, ink 880 may be any other conductive or precursor ink. One of ordinary skill in the art will recognize that the composition of ink 880 may vary based on an application or a design. Anilox roll 830 is typically constructed of a steel or aluminum core that may be coated by an industrial ceramic whose surface contains a plurality of very fine dimples, also referred to as cells (not shown). Doctor blade 840 removes excess ink 880 from anilox roll 830. In transfer area 890, anilox roll 830 meters the amount of ink 880 transferred to flexographic printing plate 860 to a uniform thickness. Printing plate cylinder 850 is typically constructed of a metal such as steel or the like. Flexographic printing plate 960 may be mounted to printing plate cylinder 850 by an adhesive (not shown). One or more transparent substrates 410 move between printing plate cylinder 850 and impression cylinder 870. Impression cylinder 870 is typically constructed of metal that is coated with an abrasion resistant coating. Impression cylinder 870 applies pressure to printing plate cylinder 850, transferring an image from flexographic printing plate 860 onto transparent substrate 410 at transfer area 895. The rotational speed of printing plate cylinder 850 is synchronized to match the speed at which substrate 410 moves through flexographic printing system 800. The speed may vary between 20 feet per minute to 750 feet per minute.

In certain embodiments, one or more flexographic printing stations 800 may be used to dispose a precursor ink, a catalytic ink, or a catalytic alloy ink 880 image (not shown) of one or more conductive patterns (e.g., first conductive pattern 420 or second conductive pattern 430) on one or more sides of one or more transparent substrates 410. Subsequent to flexographic printing, the precursor ink, the catalytic ink, or the catalytic alloy ink 880 image (not shown) may be metallized by one or more of an electroless plating process, an immersion bathing process, and/or other buildup processes, forming one or more conductive patterns (e.g., first conductive pattern 420 or second conductive pattern 430) on one or more sides of one or more transparent substrates 410. In other embodiments, a precursor ink, a catalytic ink, or a catalytic alloy ink 880 image (not shown) of one or more conductive patterns (e.g., first conductive pattern 420 or second conductive pattern 430) may be disposed on one or more sides of one or more transparent substrates 410 by any process suitable for disposing the image on substrate. Suitable processes may include, for example, printing processes, vacuum-based deposition processes, solution coating processes, or cure/etch processes that form seed lines or features on substrate that may be further processed to form conductive lines or features on substrate. Printing processes may include, in addition to the flexographic printing process previously discussed, gravure printing, inkjet printing, rotary printing, or stamp printing. Deposition processes may include pattern-based deposition, chemical vapor deposition, electro deposition, physical vapor deposition, or casting. Cure/etch processes may include optical or UV-based photolithography, e-beam/ion-beam lithography, x-ray lithography, interference lithography, scanning probe lithography, imprint lithography, or magneto lithography. One of ordinary skill in the art will recognize that any process or combination of processes, suitable for disposing an image of a conductive pattern on a substrate, may be used in accordance with one or more embodiments of the present invention.

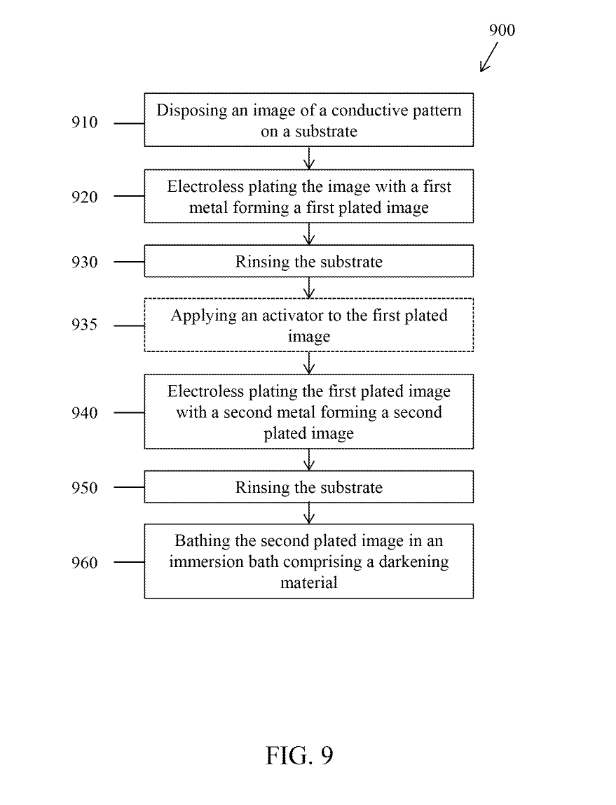

FIG. 9 shows a method 900 of fabricating a conductive pattern in accordance with one or more embodiments of the present invention. In step 910, an image of the conductive pattern may be disposed on a substrate. The image may comprise a material capable of being electroless plated. In certain embodiments, the image may comprise a precursor ink, a catalytic ink, or a catalytic alloy ink capable of being metallized by an electroless plating process. In other embodiments, the image may comprise a precursor material, catalytic material, or catalytic alloy material capable of being metallized by an electroless plating process. One of ordinary skill in the art will recognize that the composition of the image may vary in accordance with one or more embodiments of the present invention.

In certain embodiments, the image may be disposed on the substrate by a flexographic printing process. For example, one or more flexographic printing stations (800 of FIG. 8) may be used to dispose the image on a side of the substrate. In other embodiments, the image may be disposed on the substrate by any process suitable for disposing the image on substrate. Suitable processes may include, for example, other printing processes, vacuum-based deposition processes, solution coating processes, or cure/etch processes that form seed lines or features on substrate. Printing processes may include, in addition to the flexographic printing process previously discussed, gravure printing, inkjet printing, rotary printing, or stamp printing. Deposition processes may include pattern-based deposition, chemical vapor deposition, electro deposition, physical vapor deposition, or casting. Cure/etch processes may include optical or UV-based photolithography, e-beam/ion-beam lithography, x-ray lithography, interference lithography, scanning probe lithography, imprint lithography, or magneto lithography. One of ordinary skill in the art will recognize that any process, or combination of processes, suitable for disposing an image of a conductive pattern on a substrate, may be used in accordance with one or more embodiments of the present invention. In certain embodiments, the substrate may comprise PET. In other embodiments, the substrate may comprise PEN, TAC, COP, PMMA, PI, BOPP, polyester, polycarbonate, glass, copolymers, blends, or combinations thereof. In still other embodiments, the substrate may comprise any other material suitable for use as a transparent substrate. One of ordinary skill in the art will recognize that the composition of the substrate may vary based on an application or design in accordance with one or more embodiments of the present invention.

In certain embodiments, the conductive pattern may comprise a plurality of parallel conductive lines oriented in a first direction and a plurality of parallel conductive lines oriented in a second direction. In certain embodiments, the plurality of parallel conductive lines oriented in the first direction may be perpendicular to the plurality of parallel conductive lines oriented in the second direction, thereby forming a mesh. In other embodiments, the plurality of parallel conductive lines oriented in the first direction may be angled relative to the plurality of parallel conductive lines oriented in the second direction, thereby forming a mesh. One of ordinary skill in the art will recognize that the relative angle between the plurality of parallel conductive lines oriented in the first direction and the plurality of parallel conductive lines oriented in the second direction may vary based on an application or a design. In certain embodiments, the plurality of parallel conductive lines oriented in the first direction and/or the plurality of parallel conductive lines oriented in the second direction may have a line width less than 5 micrometers. In other embodiments, the plurality of parallel conductive lines oriented in the first direction and/or the plurality of parallel conductive lines oriented in the second direction may have a line width in a range between approximately 5 micrometers and approximately 10 micrometers. In still other embodiments, the plurality of parallel conductive lines oriented in the first direction and/or the plurality of parallel conductive lines oriented in the second direction may have a line width in a range between approximately 10 micrometers and approximately 50 micrometers. One of ordinary skill in the art will recognize that a line width may vary based on an application or design in accordance with one or more embodiments of the present invention.

In other embodiments, the conductive pattern may comprise any other shape or pattern formed by one or more lines or features. One of ordinary skill in the art will recognize that the conductive pattern is not limited to parallel conductive lines and could be any one or more of predetermined orientations of line segments, random orientations of line segments, curved line segments, conductive particles, polygons, or any other shape(s) or pattern(s) in accordance with one or more embodiments of the present invention.

In step 920, the image is electroless plated with a first metal forming a first plated image. In certain embodiments, the first metal may comprise copper. In other embodiments, the first metal may comprise copper alloy, such as, for example, copper nickel. In still other embodiments, the first metal may comprise one or more of nickel, silver, gold, cobalt, chromium, or ruthenium, or alloys thereof. One of ordinary skill in the art will recognize that the first metal may vary based on an application or design in accordance with one or more embodiments of the present invention. The electroless plating process may use commercially available materials suitable for electroless plating the first metal. The plating of the first metal on the image of the conductive pattern may be controlled by the duration of exposure, the constituent chemicals of the electroless plating bath, and various other constraints well known to one of ordinary skill in the art. In certain embodiments, the first metal may have a thickness in a range between approximately 100 nanometers and approximately 3 micrometers. In other embodiments, the first metal may have a thickness in a range between approximately 500 nanometers and approximately 1.5 micrometers. In still other embodiments, the first metal may have a thickness in a range between approximately 100 nanometers and approximately 500 nanometers. One of ordinary skill in the art will recognize that the first metal thickness may vary based on an application or design in accordance with one or more embodiments of the present invention.

In step 930, the substrate may be rinsed. The substrate, including the first plated image, may be rinsed to remove ions and prevent contamination of subsequent process steps, including the subsequent electroless plating and immersion bath. In certain embodiments, the substrate may be rinsed with deionized water. In other embodiments, the substrate may be rinsed with slightly acidic water to counter the basic aspect of the electroless plating bath solution. In still other embodiments, the substrate may be rinsed with a slightly basic water to counter the acidic aspect of the electroless plating bath solution. One of ordinary skill in the art will recognize that any fluid suitable for rinsing a substrate may be used in accordance with one or more embodiments of the present invention.

In step 935, an activator may optionally be applied to the first plated image. Depending on the combination of the first metal and the second metal selected, the activator may speed up the electroless plating of the second metal. While the activator may not be necessary for some combinations of metals, the application of an activator typically does not hamper the electroless plating of the second metal. In certain embodiments, where the first metal comprises copper and the second metal comprises nickel phosphorous alloy, the application of the activator may substantially speed up the electroless plating of nickel phosphorous alloy on copper. In other embodiments, where the first metal comprises copper and the second metal comprises nickel boron alloy, the application of the activator may not be necessary.

In certain embodiments, the activator may comprise a palladium based solution. In other embodiments, the activator may comprise an erbium based solution. One of ordinary skill in the art will recognize that any activator solution suitable for a particular combination of metals may be used in accordance with one or more embodiments of the present invention. In certain embodiments, the activator may be applied to the first plated image by an immersion bath comprising the activator. In other embodiments, the activator may be applied to the first plated image by a spray coating process comprising the activator. One of ordinary skill in the art will recognize that any application process suitable for applying the activator to the first plated image may be used in accordance with one or more embodiments of the present invention.

In step 940, the first plated image is electroless plated with a second metal forming a second plated image. In certain embodiments, the second metal may comprise nickel. In other embodiments, the second metal may comprise a nickel alloy, such as, for example, nickel boron alloy or nickel phosphorous alloy. In still other embodiments, the second metal may comprise cobalt. In still other embodiments, the second metal may comprise chromium. One of ordinary skill in the art will recognize that the second metal may vary based on an application or design in accordance with one or more embodiments of the present invention. The electroless plating process may use commercially available materials suitable for electroless plating the second metal. The plating of the second metal on the first plated image may be controlled by the duration of exposure, the constituent chemicals of the electroless plating bath, and various other constraints well known to one of ordinary skill in the art.

In certain embodiments, the second metal may have a thickness in a range between approximately 10 nanometers and approximately 1 micrometer. In other embodiments, the second metal may have a thickness in a range between approximately 100 nanometers and approximately 400 nanometers. In still other embodiments, the second metal may have a thickness in a range between approximately 10 nanometers and approximately 100 nanometers. One of ordinary skill in the art will recognize that the second metal thickness may vary based on an application or design in accordance with one or more embodiments of the present invention. Advantageously, the second metal passivates the first metal and provides corrosion resistance that improves long term reliability of the conductive pattern, scratch resistance from handling that improves yield, reduces the undesirable hue of the first metal, for example copper, that tends to shift the color of a display device towards copper, reduces the undesirable haze caused by the first metal, for example copper, that adversely affects the display color quality, and enhances bonding strength with a flexible cable. However, the second metal, for example nickel, tends to be reflective and as a consequence the second metal may render a conductive pattern more visible to an end user in a touch sensor application.

In step 950, the substrate may be rinsed to remove ions and prevent contamination of subsequent process steps, including the subsequent immersion bath. In certain embodiments, the substrate may be rinsed with deionized water. In other embodiments, the substrate may be rinsed with slightly acidic water to counter the basic aspect of the electroless plating bath solution. In still other embodiments, the substrate may be rinsed with a slightly basic water to counter the acidic aspect of the electroless plating bath solution. One of ordinary skill in the art will recognize that any fluid suitable for rinsing a substrate may be used in accordance with one or more embodiments of the present invention.

In step 960, the second plated image may be bathed in an immersion bath comprising a darkening material. In certain embodiments, the darkening material may comprise palladium. In other embodiments, the darkening material may comprise palladium alloys. In still other embodiments, the darkening material may comprise a compound comprising palladium. In still other embodiments, the darkening material may comprise ruthenium. In still other embodiments, the darkening material may comprise a platinum group metal or alloys thereof. One of ordinary skill in the art will recognize that the darkening material may vary based on an application or design in accordance with one or more embodiments of the present invention.

The primary reaction mechanism is direct substitution. The reaction may form a discrete layer or an intermetallic alloy such as a thin non-continuous layer that is difficult to distinguish from a thin alloy. Second metal ions are displaced by darkening material cations. In certain embodiments, nickel ions are displaced by palladium cations to form a palladium-nickel interface as well as mixed phase layers. In this way, the darkening material reduces the second metal thickness in a controlled process. For example, conditions may be controlled to regulate the darkening material/second metal interaction including, but not limited to, the duration of exposure, the temperature, and the chemical constituents of the immersion bath solution. In this way, the ratio of the darkening material to second metal may be controlled, modified, and tuned to a desired extent. Put another way, the thickness of the darkening material and the thickness reduction in the second metal may be controlled such that a desired thickness of the second metal and a desired thickness of the darkening material may be achieved. In certain embodiments, the thickness reduction in the second metal may be on the order of less than 50 nanometers.

The darkening material content may be used to control the darkening effect. In certain embodiments, the immersion bathing solution may have a darkening material content in a range between approximately 25 mg/L and approximately 1000 mg/L in order to modify the reaction rate and the resultant properties. In other embodiments, the immersion bathing solution may have a darkening material content in a range between approximately 150 mg/L and approximately 300 mg/L in order to modify the reaction rate and the resultant properties. In still other embodiments, the immersion bathing solution may have a higher darkening material content. One of ordinary skill in the art will recognize that the darkening material content may vary based on an application or design in accordance with one or more embodiments of the present invention.

In certain embodiments, the deposited darkening material may have a thickness in a range between approximately 10 nanometers and approximately 100 nanometers. In other embodiments, the deposited darkening material may have a thickness in a range between approximately 10 nanometers and approximately 50 nanometers. In still other embodiments, the deposited darkening material may have a thickness in a range between approximately 50 nanometers and approximately 100 nanometers. One of ordinary skill in the art will recognize that the deposited darkening material thickness may vary based on an application or design in accordance with one or more embodiments of the present invention. While the immersion bath process reduces the second metal content, the immersion bath process may be controlled such that the final thickness of each of the second metal and the darkening material are controlled. Advantageously, the darkening material provides a darkening effect that reduces or eliminates the reflectivity of the second metal without significantly changing the conductivity and resistivity of the conductive pattern. As such, the first metal provides the appropriate conductivity and resistivity, the second metal passivates the first metal, and the darkening material reduces the visibility of the second metal.

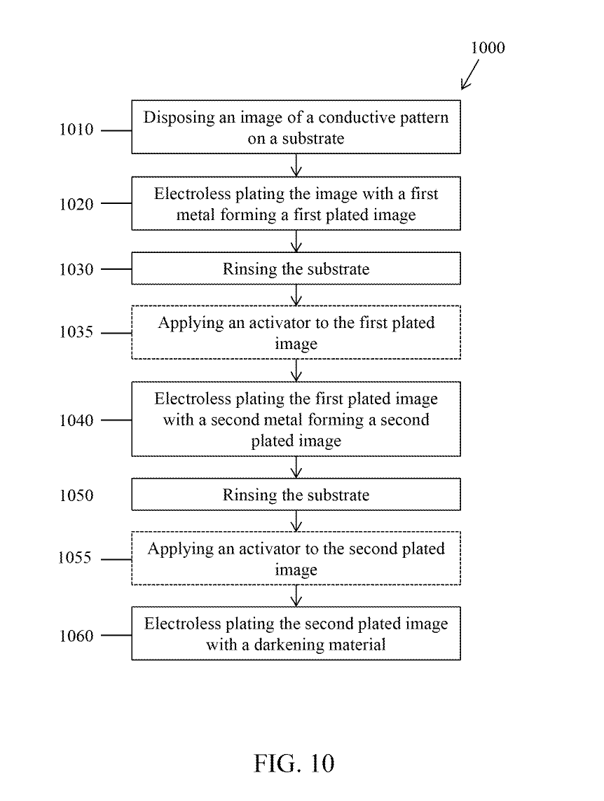

FIG. 10 shows a method 1000 of fabricating a conductive pattern in accordance with one or more embodiments of the present invention. In step 1010, an image of the conductive pattern may be disposed on a substrate. The image may comprise a material capable of being electroless plated. In certain embodiments, the image may comprise a precursor ink, a catalytic ink, or a catalytic alloy ink capable of being metallized by an electroless plating process. In other embodiments, the image may comprise a precursor material, catalytic material, or catalytic alloy material capable of being metallized by an electroless plating process. One of ordinary skill in the art will recognize that the composition of the image may vary in accordance with one or more embodiments of the present invention.

In certain embodiments, the image may be disposed on the substrate by a flexographic printing process. For example, one or more flexographic printing stations (800 of FIG. 8) may be used to dispose the image on a side of the substrate. In other embodiments, the image may be disposed on the substrate by any process suitable for disposing the image on substrate. Suitable processes may include, for example, other printing processes, vacuum-based deposition processes, solution coating processes, or cure/etch processes that form seed lines or features on substrate. Printing processes may include, in addition to the flexographic printing process previously discussed, gravure printing, inkjet printing, rotary printing, or stamp printing. Deposition processes may include pattern-based deposition, chemical vapor deposition, electro deposition, physical vapor deposition, or casting. Cure/etch processes may include optical or UV-based photolithography, e-beam/ion-beam lithography, x-ray lithography, interference lithography, scanning probe lithography, imprint lithography, or magneto lithography. One of ordinary skill in the art will recognize that any process, or combination of processes, suitable for disposing an image of a conductive pattern on a substrate, may be used in accordance with one or more embodiments of the present invention. In certain embodiments, the substrate may comprise PET. In other embodiments, the substrate may comprise PEN, TAC, COP, PMMA, PI, BOPP, polyester, polycarbonate, glass, copolymers, blends, or combinations thereof. In still other embodiments, the substrate may comprise any other material suitable for use as a transparent substrate. One of ordinary skill in the art will recognize that the composition of the substrate may vary based on an application or design in accordance with one or more embodiments of the present invention.

In certain embodiments, the conductive pattern may comprise a plurality of parallel conductive lines oriented in a first direction and a plurality of parallel conductive lines oriented in a second direction. In certain embodiments, the plurality of parallel conductive lines oriented in the first direction may be perpendicular to the plurality of parallel conductive lines oriented in the second direction, thereby forming a mesh. In other embodiments, the plurality of parallel conductive lines oriented in the first direction may be angled relative to the plurality of parallel conductive lines oriented in the second direction, thereby forming a mesh. One of ordinary skill in the art will recognize that the relative angle between the plurality of parallel conductive lines oriented in the first direction and the plurality of parallel conductive lines oriented in the second direction may vary based on an application or a design. In certain embodiments, the plurality of parallel conductive lines oriented in the first direction and/or the plurality of parallel conductive lines oriented in the second direction may have a line width less than 5 micrometers. In other embodiments, the plurality of parallel conductive lines oriented in the first direction and/or the plurality of parallel conductive lines oriented in the second direction may have a line width in a range between approximately 5 micrometers and approximately 10 micrometers. In still other embodiments, the plurality of parallel conductive lines oriented in the first direction and/or the plurality of parallel conductive lines oriented in the second direction may have a line width in a range between approximately 10 micrometers and approximately 50 micrometers. One of ordinary skill in the art will recognize that a line width may vary based on an application or design in accordance with one or more embodiments of the present invention.

In other embodiments, the conductive pattern may comprise any other shape or pattern formed by one or more lines or features. One of ordinary skill in the art will recognize that the conductive pattern is not limited to parallel conductive lines and could be any one or more of predetermined orientations of line segments, random orientations of line segments, curved line segments, conductive particles, polygons, or any other shape(s) or pattern(s) in accordance with one or more embodiments of the present invention.

In step 1020, the image is electroless plated with a first metal forming a first plated image. In certain embodiments, the first metal may comprise copper. In other embodiments, the first metal may comprise copper alloy, such as, for example, copper nickel. In still other embodiments, the first metal may comprise one or more of nickel, silver, gold, cobalt, chromium, or ruthenium, or alloys thereof. One of ordinary skill in the art will recognize that the first metal may vary based on an application or design in accordance with one or more embodiments of the present invention. The electroless plating process may use commercially available materials suitable for electroless plating the first metal. The plating of the first metal on the image of the conductive pattern may be controlled by the duration of exposure, the constituent chemicals of the electroless plating bath, and various other constraints well known to one of ordinary skill in the art. In certain embodiments, the first metal may have a thickness in a range between approximately 100 nanometers and approximately 3 micrometers. In other embodiments, the first metal may have a thickness in a range between approximately 500 nanometers and approximately 1.5 micrometers. In still other embodiments, the first metal may have a thickness in a range between approximately 100 nanometers and approximately 500 nanometers. One of ordinary skill in the art will recognize that the first metal thickness may vary based on an application or design in accordance with one or more embodiments of the present invention.

In step 1030, the substrate may be rinsed. The substrate, including the first plated image, may be rinsed to remove ions and prevent contamination of subsequent process steps, including the subsequent electroless plating steps. In certain embodiments, the substrate may be rinsed with deionized water. In other embodiments, the substrate may be rinsed with slightly acidic water to counter the basic aspect of the electroless plating bath solution. In still other embodiments, the substrate may be rinsed with a slightly basic water to counter the acidic aspect of the electroless plating bath solution. One of ordinary skill in the art will recognize that any fluid suitable for rinsing a substrate may be used in accordance with one or more embodiments of the present invention.

In step 1035, an activator may optionally be applied to the first plated image. Depending on the combination of the first metal and the second metal selected, the activator may speed up the electroless plating of the second metal. While the activator may not be necessary for some combinations of metals, the application of an activator typically does not hamper the electroless plating of the second metal. In certain embodiments, where the first metal comprises copper and the second metal comprises nickel phosphorous alloy, the application of the activator may substantially speed up the electroless plating of nickel phosphorous alloy on copper. In other embodiments, where the first metal comprises copper and the second metal comprises nickel boron alloy, the application of the activator may not be necessary.

In certain embodiments, the activator may comprise a palladium based solution. In other embodiments, the activator may comprise an erbium based solution. One of ordinary skill in the art will recognize that any activator solution suitable for a particular combination of metals may be used in accordance with one or more embodiments of the present invention. In certain embodiments, the activator may be applied to the first plated image by an immersion bath comprising the activator. In other embodiments, the activator may be applied to the first plated image by a spray coating process comprising the activator. One of ordinary skill in the art will recognize that any application process suitable for applying the activator to the first plated image may be used in accordance with one or more embodiments of the present invention.

In step 1040, the first plated image is electroless plated with a second metal forming a second plated image. In certain embodiments, the second metal may comprise nickel. In other embodiments, the second metal may comprise a nickel alloy, such as, for example, nickel boron alloy or nickel phosphorous alloy. In still other embodiments, the second metal may comprise cobalt. In still other embodiments, the second metal may comprise chromium. One of ordinary skill in the art will recognize that the second metal may vary based on an application or design in accordance with one or more embodiments of the present invention. The electroless plating process may use commercially available materials suitable for electroless plating the second metal. The plating of the second metal on the first plated image may be controlled by the duration of exposure, the constituent chemicals of the electroless plating bath, and various other constraints well known to one of ordinary skill in the art.

In certain embodiments, the second metal may have a thickness in a range between approximately 10 nanometers and approximately 500 nanometers. In other embodiments, the second metal may have a thickness in a range between approximately 100 nanometers and approximately 200 nanometers. In still other embodiments, the second metal may have a thickness in a range between approximately 200 nanometers and approximately 500 nanometers. One of ordinary skill in the art will recognize that the second metal thickness may vary based on an application or design in accordance with one or more embodiments of the present invention. Advantageously, the second metal passivates the first metal and provides corrosion resistance that improves long term reliability of the conductive pattern, scratch resistance from handling that improves yield, reduces the undesirable hue of the first metal, for example copper, that tends to shift the color of a display device towards copper, reduces the undesirable haze caused by the first metal, for example copper, that adversely affects the display color quality, and enhances bonding strength. However, the second metal, for example nickel, tends to be reflective and as a consequence the second metal may render a conductive pattern more visible to an end user in a touch sensor application.

In step 1050, the substrate may be rinsed to remove ions and prevent contamination, including the subsequent electroless plating. In certain embodiments, the substrate may be rinsed with deionized water. In other embodiments, the substrate may be rinsed with slightly acidic water to counter the basic aspect of the electroless plating bath solution. In still other embodiments, the substrate may be rinsed with a slightly basic water to counter the acidic aspect of the electroless plating bath solution. One of ordinary skill in the art will recognize that any fluid suitable for rinsing a substrate may be used in accordance with one or more embodiments of the present invention.

In step 1055, an activator may optionally be applied to the second plated image. Depending on the combination of the second metal and the darkening material, the activator may speed up electroless plating of the darkening material. While the activator may not be necessary for some combinations of metals, the application of an activator typically does not hamper the electroless plating of the darkening material.

In certain embodiments, the activator may comprise a palladium based solution. In other embodiments, the activator may comprise an erbium based solution. One of ordinary skill in the art will recognize that any activator solution suitable for a particular combination of metals may be used in accordance with one or more embodiments of the present invention. In certain embodiments, the activator may be applied to the second plated image by an immersion bath comprising the activator. In other embodiments, the activator may be applied to the second plated image by a spray coating process comprising the activator. One of ordinary skill in the art will recognize that any application process suitable for applying the activator to the second plated image may be used in accordance with one or more embodiments of the present invention.

In step 1060, the second plated image is electroless plated with a darkening material. In certain embodiments, darkening material may comprise zinc. In other embodiments, the darkening material may comprise niobium. In still other embodiments, the darkening material may comprise cobalt. In still other embodiments, the darkening material may comprise selenium. In still other embodiments, the darkening material may comprise antimony. In still other embodiments, the darkening material may comprise tellurium. One of ordinary skill in the art will recognize that the darkening material may vary based on an application or design in accordance with one or more embodiments of the present invention. The electroless plating process may use commercially available materials suitable for electroless plating the darkening material. The plating of the darkening material on the second plated image may be controlled by the duration of exposure, the constituent chemicals of the electroless plating bath, and various other constraints well known to one of ordinary skill in the art. In certain embodiments, the darkening material may have a thickness in a range between approximately 10 nanometers and approximately 100 nanometers.

In other embodiments, the deposited darkening material may have a thickness in a range between approximately 10 nanometers and approximately 50 nanometers. In still other embodiments, the deposited darkening material may have a thickness in a range between approximately 50 nanometers and approximately 100 nanometers. In still other embodiments, the deposited darkening material may have a thickness in a range between approximately 50 nanometers and approximately 100 nanometers. One of ordinary skill in the art will recognize that the deposited darkening material thickness may vary based on an application or design in accordance with one or more embodiments of the present invention. Advantageously, the darkening material provides a darkening effect that reduces or eliminates the reflectivity of the second metal without significantly changing the conductivity and resistivity of the conductive pattern. As such, the first metal provides the appropriate conductivity and resistivity, the second metal passivates the first metal, and the darkening material reduces the visibility of the second metal.

Advantages of one or more embodiments of the present invention may include one or more of the following:

In one or more embodiments of the present invention, a method of fabricating a conductive pattern provides high optical transmission and low visibility.

In one or more embodiments of the present invention, a method of fabricating a conductive pattern reduces the undesirable hue of, for example, a copper base metal that tends to shift the color of a display device towards copper.

In one or more embodiments of the present invention, a method of fabricating a conductive pattern reduces the undesirable haze of, for example, a copper base metal that adversely affects the display color quality.

In one or more embodiments of the present invention, a method of fabricating a conductive pattern reduces or eliminates the reflectivity of the conductive pattern.

In one or more embodiments of the present invention, a method of fabricating a conductive pattern provides substantially similar electrical conductivity/resistivity performance.

In one or more embodiments of the present invention, a method of fabricating a conductive pattern improves reliability and resists environmental degradation. A second metal may passivate a first metal thereby providing corrosion resistance that improves the long term reliability of the conductive pattern.

In one or more embodiments of the present invention, a method of fabricating a conductive pattern enhances bonding strength with a flexible cable.

In one or more embodiments of the present invention, a method of fabricating a conductive pattern improves yield. Because of the passivation, the conductive pattern is scratch resistant and less prone to failures from handling.

In one or more embodiments of the present invention, a method of fabricating a conductive pattern reduces manufacturing expense, manufacturing time, and manufacturing complexity.

In one or more embodiments of the present invention, a method of fabricating a conductive pattern uses an immersion bath that limits the amount of darkening material needed to darken the second metal. For example, the use of an immersion bath limits the amount of expensive chemicals necessary to produce the darkening effect and saves material cost.

In one or more embodiments of the present invention, a method of fabricating a conductive pattern is compatible with flexographic printing processes.

In one or more embodiments of the present invention, a method of fabricating a conductive pattern is compatible with other conductive pattern fabrication processes.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should be limited only by the appended claims.

What is claimed is:

1. A method of fabricating a conductive pattern comprising:
disposing an image of the conductive pattern on a substrate, wherein the image comprises material capable of being electroless plated;
electroless plating the image with a first metal forming a first plated image;
electroless plating the first plated image with a second metal forming a second plated image, wherein the second metal passivates the first metal; and
bathing the second plated image in an immersion bath comprising a darkening material.

2. The method of claim 1, further comprising rinsing the substrate with deionized water.

3. The method of claim 1, further comprising applying an activator to the first plated image.

4. The method of claim 1, wherein the image of the conductive pattern is disposed on the substrate by a flexographic printing process.

5. The method of claim 4, wherein the image comprises a catalytic ink.

6. The method of claim 1, wherein the substrate comprises polyethylene terephthalate.

7. The method of claim 1, wherein the conductive pattern comprises a plurality of parallel conductive lines oriented in a first direction and a plurality of parallel conductive lines oriented in a second direction.

8. The method of claim 7, wherein the conductive lines have a line width of less than 5 micrometers.

9. The method of claim 7, wherein the conductive lines have a line width in a range between approximately 5 micrometers and approximately 10 micrometers.

10. The method of claim 1, wherein the first metal comprises copper.

11. The method of claim 1, wherein the first metal comprises copper nickel alloy.

12. The method of claim 1, wherein the first metal comprises one or more of nickel, silver, gold, cobalt, chromium, or ruthenium.

13. The method of claim 1, wherein the first metal thickness is in a range between approximately 100 nanometers and approximately 3 micrometers.

14. The method of claim 1, wherein the first metal thickness is in a range between approximately 500 nanometers and approximately 1.5 micrometers.

15. The method of claim 1, wherein the first metal thickness is in a range between approximately 100 nanometers and approximately 500 nanometers.

16. The method of claim 1, wherein the second metal comprises nickel.

17. The method of claim 1, wherein the second metal comprises nickel boron alloy.

18. The method of claim 1, wherein the second metal comprises nickel phosphorous alloy.

19. The method of claim 1, wherein the second metal comprises cobalt.

20. The method of claim 1, wherein the second metal comprises chromium.

21. The method of claim 1, wherein the second metal thickness is in a range between approximately 10 nanometers and approximately 1 micrometer.

22. The method of claim 1, wherein the second metal thickness is in a range between approximately 100 nanometers and approximately 400 nanometers.

23. The method of claim 1, wherein the second metal thickness is in a range between approximately 10 nanometers and approximately 100 nanometers.

24. The method of claim 1, wherein the darkening material comprises palladium.

25. The method of claim 1, wherein the darkening material comprises ruthenium.

26. The method of claim 1, wherein the darkening material comprises a platinum group metal.

27. The method of claim 1, wherein the darkening material thickness is in a range between approximately 10 nanometers and approximately 100 nanometers.

28. The method of claim 1, wherein the darkening material thickness is in a range between approximately 10 nanometers and approximately 50 nanometers.

29. The method of claim 1, wherein the darkening material thickness is in a range between approximately 50 nanometers and approximately 100 nanometers.

30. A method of fabricating a conductive pattern comprising:
disposing an image of the conductive pattern on a substrate, wherein the image comprises material capable of being electroless plated;
electroless plating the image with a first metal forming a first plated image;
electroless plating the first plated image with a second metal forming a second plated image, wherein the second metal passivates the first metal; and
electroless plating the second plated image with a darkening material.

31. The method of claim 30, further comprising rinsing the substrate with deionized water.

32. The method of claim 30, further comprising applying an activator to the first plated image.

33. The method of claim 30, further comprising applying an activator to the second plated image.

34. The method of claim 30, wherein the image of the conductive pattern is disposed on the substrate by a flexographic printing process.

35. The method of claim 34, wherein the image comprises a catalytic ink.

36. The method of claim 30, wherein the substrate comprises polyethylene terephthalate.

37. The method of claim 30, wherein the conductive pattern comprises a plurality of parallel conductive lines oriented in a first direction and a plurality of parallel conductive lines oriented in a second direction.

38. The method of claim 37, wherein the conductive lines have a line width of less than 5 micrometers.

39. The method of claim 37, wherein the conductive lines have a line width in a range between approximately 5 micrometers and approximately 10 micrometers.

40. The method of claim 30, wherein the first metal comprises copper.

41. The method of claim 30, wherein the first metal comprises copper nickel alloy.

42. The method of claim 30, wherein the first metal comprises one or more of nickel, silver, gold, cobalt, chromium, or ruthenium.

43. The method of claim 30, wherein the first metal plated thickness is in a range between approximately 100 nanometers and approximately 3 micrometers.

44. The method of claim 30, wherein the first metal plated thickness is in a range between approximately 500 nanometers and approximately 1.5 micrometers.

45. The method of claim 30, wherein the first metal plated thickness is in a range between approximately 100 nanometers and approximately 500 nanometers.

46. The method of claim 30, wherein the second metal comprises nickel.

47. The method of claim 30, wherein the second metal comprises nickel boron alloy.

48. The method of claim 30, wherein the second metal comprises nickel phosphorous alloy.

49. The method of claim 30, wherein the second metal comprises cobalt.

50. The method of claim 30, wherein the second metal comprises chromium.

51. The method of claim 30, wherein the second metal plated thickness is in a range between approximately 10 nanometers and approximately 500 nanometers.

52. The method of claim 30, wherein the second metal plated thickness is in a range between approximately 100 nanometers and approximately 200 nanometers.

53. The method of claim 30, wherein the second metal plated thickness is in a range between approximately 200 nanometers and approximately 500 nanometers.

54. The method of claim 30, wherein the darkening material comprises zinc.

55. The method of claim 30, wherein the darkening material comprises niobium.

56. The method of claim 30, wherein the darkening material comprises cobalt.

57. The method of claim 30, wherein the darkening material thickness is in a range between approximately 10 nanometers and approximately 100 nanometers.

58. The method of claim 30, wherein the darkening material thickness is in a range between approximately 10 nanometers and approximately 50 nanometers.

59. The method of claim 30, wherein the darkening material thickness is in a range between approximately 50 nanometers and approximately 100 nanometers.
